(19) United States
(12) Patent Application Publication
(10) Pub. No.: US 2011/0109414 A1
(43) Pub. Date: May 12, 2011

(54) METHOD FOR PRODUCING A COIL FROM SHEET METAL AND COIL

(76) Inventors: Hugo Peerenboom, Juelich (DE); Harald Glueckler, Juelich (DE); Juergen Collienne, Aachen (DE)

(21) Appl. No.: 12/737,355

(22) PCT Filed: Jun. 17, 2009
(86) PCT No.: PCT/DE2009/000835

§ 371 Date: Jan. 19, 2011

(30) Foreign Application Priority Data
Jul. 22, 2008 (JP) 10 2008 034 067.7

(51) Int. Cl. H01F 27/30; H01F 41/04; G01R 33/44; H01F 5/02

(52) U.S. Cl. 336/199; 29/602.1; 324/318

(57) ABSTRACT

Disclosed is a method for producing a coil from sheet metal comprising producing a carrier plate having spacers for the sheet metal; fastening the sheet metal to the spacers of the carrier plate; and fabricating a coil geometry in the sheet metal. The stabilized sheet metal is excellent to work. The coil, including the windings, can be fixed so as to keep the windings separate from each other, both spatially and electrically.

The invention relates to a method for producing a coil and to a coil, such as those which are used in magnetic resonance tomography (also referred to as magnetic resonance imaging, MRI).

Magnetic resonance imaging has been employed for many years as an imaging method in medicine and biophysics. In this examination method, the object is exposed to a strong, constant magnetic field. As a result, the nuclear spins of the atoms in the object, which previously had been irregularly aligned, are aligned. Radio frequency waves can then excite these “orderly” nuclear spins to produce a certain oscillation (resonance frequency). These oscillations generate the proper measurement signal (response signal) in magnetic resonance imaging, this signal being received using suitable receiving coils.

For the examination of small organisms having accordingly small dimensions in the magnetic resonance imaging scanner, appropriate coils are necessary to generate the required fields. Common methods for producing coils comprise steps such as milling, (laser) cutting, and forming and bending materials made of sheet metal.

Some examinations on living objects necessitate extremely small coils. These coils are disposed with the individual coils at a small distance from each other and have small material cross-sections and thin windings. Thin sheet metals are used as starting materials for producing the coils. Given this starting situation, the aforementioned manufacturing techniques fail. For example, it is not possible to simply mill a flat coil from thin sheet metal, or to cut it out using a laser. The sheet metal would become unstable, and the coil would lose its shape. However, to generate electromagnetic (radio frequency) fields, coils are required that have narrow windings and geometries specified by calculations, and to be made of thin, metallic materials. Producing thin sheet metal having very low inherent stability in such a way as to produce a coil is not possible with the aforementioned techniques.

It is the object of the invention to provide another method for producing a coil, which does not exhibit the disadvantages known from the prior art. It is a further object of the invention to provide a corresponding coil and describe the intended use thereof.

The object is achieved by a method according to claim 1 and by an assembly or coil, and the uses thereof, according to the additional independent claims. Advantageous embodiments will be apparent from the claims that are dependent on these claims.

The method for producing a coil from sheet metal comprises the following steps:
producing a carrier plate having spacers for the sheet metal,
fastening the sheet metal to the spacers of the carrier plate, and
fabricating a coil geometry in the sheet metal.

The method advantageously makes it possible to produce small coils having low winding thicknesses.

Fabricating the coil geometry substantially concludes the method for producing the coil. During the fabrication of the coil geometry, the sheet metal for the coil is stabilized by the spacers, notably in the region of the windings.

The coil is then once again detached from the spacers. In a purely optional manner, the coil geometry that was fabricated, including the winding, is fixed prior to detachment and cleaned after being detached.

A support is milled for the carrier plate, preferably from a metallic block. In the region of the spacers, the carrier plate forms the negative undersurface of the coil and serves as the support surface for the coil during fabrication of the same by way of the spacers disposed in the carrier plate. For this purpose, the carrier plate comprises the spacers on the surface thereof, preferably in the form of individual, optionally narrow, ribs, ridges or strips for the coil sheet metal. It is conceivable to provide narrow, button-like structures as the spacers. The spacers can preferably be worked from the material of the carrier plate, for example by milling. They must be designed so as to ensure that the coil sheet metal remains rigidly fastened to the spacers during the subsequent machining operation.

The spacers are disposed in or on the carrier plate. The spacers support the dimensionally unstable windings of the coil to be fabricated during production of the same. The spacers are narrow so that, at the underside of the coil sheet metal, only a comparatively small contact surface is seated against the region where the windings are to be. The height of the spacer is such that the coil sheet metal can be placed on the spacers and fastened to the upper edges thereof. In the region of the windings, the spacers are adapted to the two- or three-dimensional geometry of the coil sheet metal to be supported, so that the sheet metal can be fastened to the upper edge of the spacers. The height of the spacers and the surface area on which they are disposed, on or in the carrier plate, are adapted to the coil geometry to be fabricated.

The thickness of the spacers is 0.3 millimeters or the like. The height of the spacers is approximately 4 millimeters or the like. This is preferably identical for all spacers, provided that a flat coil sheet metal is to be fastened thereon and then machined. Of course, it is also possible to select dimensions that differ from these, depending on the material that is used, and depending on how the coil geometry and the thickness, as well as the distances, of the windings are configured.

A sheet metal section is produced for the coil, for example by way of cutting it out. For flat coils, sheet metals made of copper or the like are cut out with an overmeasure relative to the final dimensions. Uniaxially curved coil sheet metals are subsequently bent to the desired radius. Other manufacturing methods must be employed for multiaxially arched coils, for example deep-drawing so as to produce suitable sheet metals. The method can therefore be employed universally and is also suited for thin, small coils that are to be produced three-dimensionally.

In order to produce arched surfaces on the sheet metal for the coil, the desired surface can be incorporated into a thick sheet metal piece by way of milling, either only on one side at first, or on both sides from the start. To produce a three-dimensionally arched coil, the height of the spacers is again adapted to geometry of the sheet metal, so that all of them can be fastened to the sheet metal and support it during further machining.

The sheet metal for the coil is placed onto the carrier plate spacers and fastened thereto. Because the spacers, in terms of the heights thereof, constitute negatives with respect to the coil sheet metal, the sheet metal for the coil lays closely against the spacers in the region where the windings are to be. Spacers are preferably fastened to the sheet metal over the entire region of the windings, in such a manner that they maintain the shapes thereof during the production of the windings.

A material having low thermal capacity is preferably selected for the carrier plate. For example, brass may be selected as the material. Brass advantageously has low heat capacity, so that, for the purpose of maintaining the shape of the spacers, a brazing method can be selected for fastening the coil sheet metal to the spacers of the carrier plate.

The coil sheet metal can be brazed onto the spacers using silver filler or the like. Soft soldering or hard soldering methods can be used as the joining method. The necessary heat can be generated by a soldering iron, a soldering flame, a heating plate, or in a brazing furnace.

Of course it is also possible to select a different fastening method for fastening the sheet metal to the spacers of the carrier plate. For example, the coil sheet metal may also be glued onto the spacers of the carrier plate. The material of the carrier plate, and the spacers produced therefrom, then do not necessarily have to have low heat capacity.

The materials of the coil sheet metal and of the carrier plate as well as the work method are matched to each other so as to fasten and machine the coil.

In particular, copper is a standard material that may be used for the sheet metal of the coil. Of course it is also possible to select a different material, notably a different metal, such as aluminum.

Using these steps, a flat or arbitrarily three-dimensionally arched sheet metal made of copper can be brazed or glued onto the spacers of the carrier plate, which is made of brass.

If the sheet metal for the arched coil has been adapted to the carrier plate or spacers only on one side, the rear (upper) surface is then machined by way of a milling operation or the like, so as to yield the desired, thin (three-dimensional) sheet metal contour on the carrier plate. It is not necessary to fasten a thin sheet metal on the carrier plate from the start. Instead, a thick three-dimensionally curved sheet metal can be further machined, after being fastened to the spacers, until it has reached a state in which it is fastened to the spacers as a thin three-dimensionally curved sheet metal. After the sheet metal for the coil has been fastened to the spacers of the carrier plate, and optionally finished, the coil geometry is fabricated in the thin sheet metal that is fastened and stabilized in this way.

The coil geometry denotes the finished coil comprising the windings in the coil sheet metal on the carrier plate. The coil geometry encompasses the number of coil windings, the thicknesses thereof, the gauges and the distances of the windings to each other and, in the case of arched three-dimensional coils, the three-dimensional surface.

The fastened coil sheet metal is always sufficiently stabilized in at least the region of the windings by the spacers of the carrier plate so that it can be machined, for example by a laser or a milling unit. Laser machining using a fine cutting laser creates, by way of laser cutting, the fine separating channels that separate the individual coil windings from each other, both electrically and spatially. The laser makes it possible to create separating slits ranging between several 1/10 mm and 1/100 mm, depending on the material type and thickness and the laser power.

Thereafter, the outside dimensions of the sheet metal are finished. After removing the cutting burr, all machining residue is removed from the part, and the part is optionally cleaned.

In a particularly advantageous embodiment, the coil sheet metal is cut out in the desired shape using an ND:YAG laser. In this way, the coil geometry, including the windings, is fabricated in the coil sheet metal. The narrowest cut is the cutting width of the laser and is approximately 1/100 millimeter. The thickness of the individual windings advantageously ranges between 0.05 and 1 millimeter.

In an alternative embodiment of the invention, the coil geometry is milled. The (coil) sheet metal is kept in the shape thereof by the structure of the carrier plate having the spacers, which is brazed-on or otherwise fastened thereto. The spacers of the substructure do not interfere with the tool that is used to produce the coil geometry, such as the laser or milling tool.

After the production of the coil geometry is complete, the windings and the distances from each other, as well as the surface area on which they are disposed, are determined.

In a particularly advantageous embodiment of the invention, the coil geometry is then fixed. This fixation permanently separates the windings from each other, both spatially and electrically. In this way, the coil can be separated afterwards from the spacers without losing its shape.

For this purpose, adhesive alone can be applied to the coil geometry, which can then be allowed cure. To this end, a polymerization adhesive may be selected. The adhesive can be applied onto the coil sheet metal directly after producing the windings, and the sheet metal can be removed from the carrier plate immediately after curing.

Preferably a thin, non-conductive isolator is glued to the free side of the coil, opposite from the spacers. The isolator may be a plastic film, or simply a potting compound made of adhesive, so long as it allows a sufficiently stabilizing layer to be created on the coil surface.

In the case of a flat coil, a thin plastic film or plate made of plexiglass or the like is preferably used, which is glued to the coil using Acrifix 190®. For curved three-dimensional coils, this fixating negative mold must first be worked from a thicker plastic plate, for example by way of a milling operation. As an alternative, it is also possible to first embed the entire coil in plastic and then work the desired surface shape by way of a milling operation, for example.

The plastic carrier is joined to the coil on the carrier plate using a suitable adhesive, for example Acrifix 190®. The adhesive bonds the plastic selected to the coil material with sufficient strength, and additionally penetrates well into the fine separating gaps of the coil, so as to lastingly isolate them and the windings from each other.

After the adhesive bond has cured, the carrier plate having the spacers is detached from the optionally fixed coil sheet metal. Then, the residue of the spacers is removed from the surface of the coil, preferably by way of a milling operation. Adhesive that seeped through toward the carrier plate during gluing is also removed in the process.

The coil geometry can be fixed using any thin plastic plate and a suitable, notably low-viscosity, adhesive. The adhesive penetrates as an isolator into the separating slits that were created between the windings of the coil and fixes them electrically and spatially separated from each other in a lasting manner.

This fixation, however, can be foregone, provided that the material and the geometry of the coil have sufficient inherent stability. As a result, depending on these parameters, the method does not necessarily have to comprise fixation of the finished coil geometry.

The preferably fixed coil geometry is then separated from the carrier plate and the spacers using a severing method. For this purpose, a mechanical separation method is advantageously employed. Optionally, the surface of the exposed and preferably fixed coil is cleaned.

In the case of flat or minimally curved coils, the carrier plate can first be roughly sawed off in the region of the ridges at a sufficient distance from the coil sheet metal. In the case of significantly curved coil sheet metals, the carrier plate may have to be machined as a whole.

As the end product, the exposed coil made of thin sheet metal, having tight and narrowly separated windings; is preferably fastened to a non-conductive plastic carrier material, which can be installed in the application system and electrically connected.

The method described is suited for flat coils. However, as was shown, it may also be applied, without any limitations, to the production of curved three-dimensional coil geometries.

For the coil sheet metal, the carrier plate bears the spacers so as to be able to support the coil sheet metal in the region of the coil to be produced and machine it. Of course the carrier plate may have larger dimensions than the coil sheet metal, or the resulting coil geometry, for example to allow better handling.

It is evident that a carrier plate comprising the spacer's and the thin sheet metal fastened thereon for a production method of a coil constitutes progress. It is also conceivable to supply the coil, still fastened to the spacers, to the intended purpose.

In a particularly advantageous embodiment, coils having windings at a distance of less than 1 millimeter are provided. The coils are preferably fixed using an adhesive, or are present fixed by way of an adhesive on a non-conductive plastic carrier.

It is possible, for example, to produce 9 to 10 windings of a coil, separated from each other by a 0.03 millimeter separating slit, in a base area of less than 5 cm². It is conceivable to produce such coils on surface areas measuring less than 5 cm² using the method.

In a particularly advantageous further embodiment of the invention, entire coil systems comprising a plurality of coils, for example two or three individual coils, can be provided from one metal sheet in one operation. These multi-coil systems already have the intended spatial arrangement with respect to each other.

The coils according to the invention may be used, for example, in a magnetic resonance imaging scanner with extreme space constraints. They can usually withstand very high currents of approximately 20 A with pulses of 1 ms.

The invention will be described in more detail below with reference to two embodiments and the accompanying figures.

### FIRST EMBODIMENT

### Production of a Flat Coil

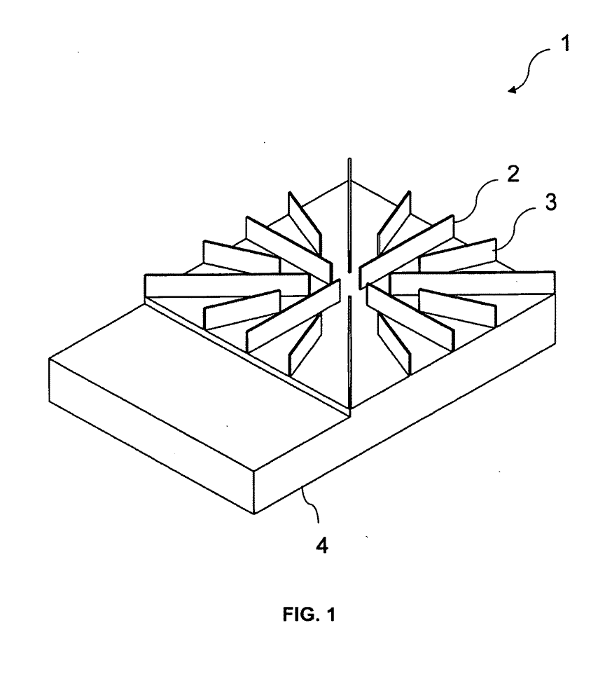

FIG. 1: top view of a carrier plate comprising spacers,

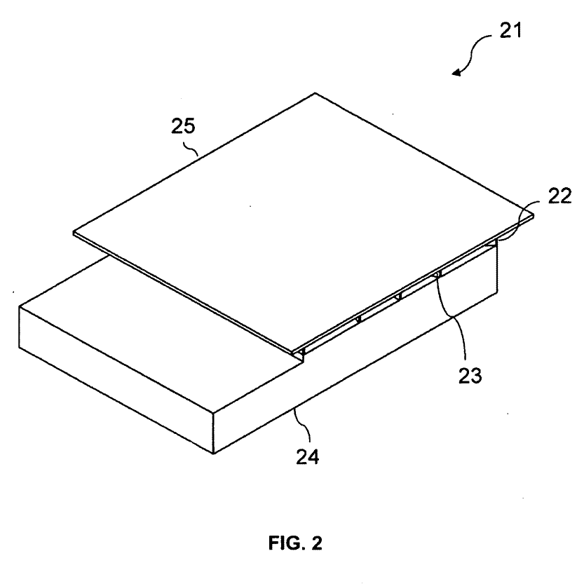

FIG. 2: top view of assembly 21, comprising a sheet metal fastened to a carrier plate,

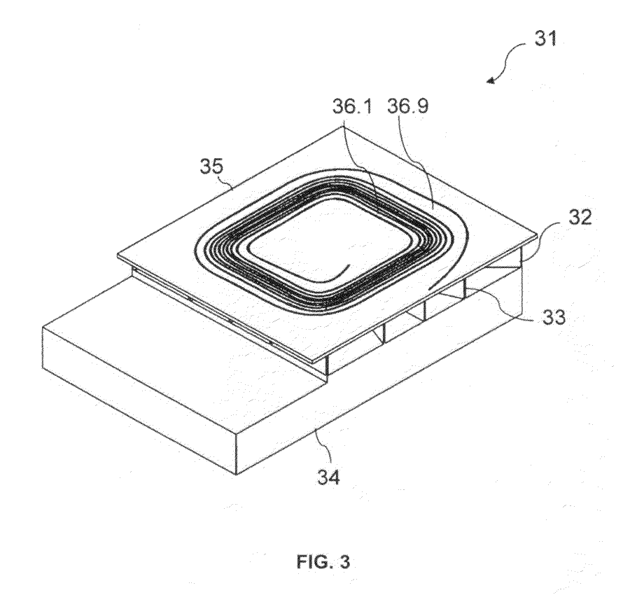

FIG. 3: top view of assembly 31, comprising a sheet metal fastened to a carrier plate after fabricating the coil geometry,

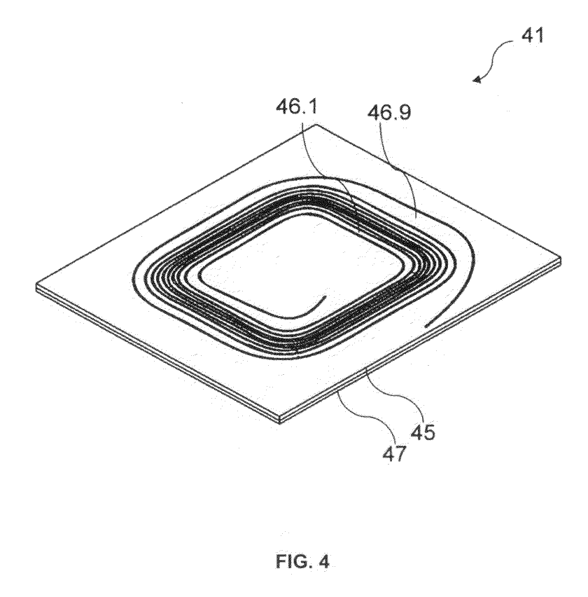

FIG. 4: top view of an exposed coil, fixed onto a plastic carrier.

In a first step, an assembly 1 comprising the carrier plate 4 and spacers 2, 3 is created. The carrier plate 4 is made of brass. The carrier plate 4 may be regarded as a support plate for the coil sheet metal (not shown). In the region of the spacers, the carrier plate 4 constitutes a negative mold for the coil geometry to be fabricated.

The carrier plate has a total thickness of 10 millimeters (including the spacers), a length of 47 millimeters, and a width of 32 millimeters.

The surface of the carrier plate 4 comprising the spacers is produced by milling a brass block. For this purpose, slits measuring approximately 3 mm in depth are milled into the surface of the material of the brass block, whereby narrow ridges having a wall thickness of approximately 0.3 mm are obtained. These remain as spacers 2, 3 after the material has been removed.

FIG. 1 therefore shows eight longer ridges 2, of which only one is denoted with reference numeral 2. FIG. 1 also shows eight short ridges 3, of which again only one is denoted with reference numeral 3. The short and long ridges 3, 2 are disposed alternately and form the spacers of the carrier plate 4. In the further course of the method, the ridges 2, 3 constitute the spacers from the sheet metal for the coil. In this way, a coil carrier that is composed of spacers and a carrier plate is produced, which has the same three-dimensional surface as the sheet metal from which the coil is manufactured.

In a second step of the method, a sheet metal made of copper, in which the coil geometry is fabricated, is fastened to the spacers of the carrier plate, so that an assembly 21 comprising a carrier plate 24 having the spacers 22, 23 and a fastened copper sheet metal 25 is formed. The coil sheet metal is placed onto the upper edges of the spacers and is seated thereon. The sheet metal is referred to as the coil sheet metal 25. It has a thickness of 0.5 millimeters and a height and width of 32 millimeters, respectively. This surface area agrees with the surface area in which the spacers are disposed.

The coil sheet 25 is brazed onto the spacers 22, 23 and the shape thereof is maintained or stabilized. The necessary heat can be generated by a soldering iron, the soldering flame, a heating plate, or by a brazing furnace into which the assembly comprising the coil sheet metal and carrier plate is placed.

The free surface area of the carrier plate 24, which is not covered by the coil sheet metal, shown in the left of the figure, is provided for better handling of the assembly 21.

After the second step of the method, the coil sheet metal 25 is fastened to the carrier plate 24 by way of the spacers 22, 23, without the coil sheet metal or the carrier plate comprising the spacers being deformed in the process. It is ensured that the ridges 22, 23 maintain their shapes in the heat that develops during brazing.

In the third step of the method, the coil geometry is fabricated in the fastened sheet metal 25 using a laser cutting system so as to create the assembly 31.

The brazed coil sheet metal 35 is further stabilized during cutting by the carrier plate 34 comprising the spacers 32, 33. During this machining step, the coil sheet 35 maintains the its shape and neither this nor the supporting spacers bend under the heat that develops.

The slit, which is shown in dark color, separates the windings 36.1 (inside) to 36.9 (outside), which are shown in light color, from each other. The laser machining operation creates the fine separating channels, which electrically separate the individual coil windings shown in light color from each other, by way of laser cutting.

The separating slit, which is a hollow space present between the windings measuring 0.03 mm, was made by the laser. The thickness of the windings is 0.05 to 1 millimeter.

In this way, after step 3 of the method, the coil has been created. The finished coil sheet metal 35 comprises the required windings. It is possible to machine very thin sheet metals and produce the corresponding coils, simply by way of the aforementioned three steps.

After this, the outside dimensions of the sheet metal are finished. After removing the cutting burr, machining residue is cleaned from the coil sheet metal. Optionally, it may also be thoroughly cleaned.

Preferably, in the fourth and final step of the method, the coil geometry fabricated in this way may be fixed. Given the aforementioned small dimensions, this step is advantageous with a view to further stabilizing the coil.

For this purpose, the coil sheet metal 35 having the windings 36.1 to 36.9 is glued onto a plastic carrier. The plastic carrier is glued onto the free surface of the coil sheet metal using a two-component polymerization adhesive (Acrifix 190®). For this purpose, a plate made of plexiglass is used. This plate preferably has a thickness of as little as 1/10 millimeter. This plastic carrier must, of course, also have the same surface geometry as the coil.

The plexiglass plastic carrier is glued to the coil in this way. The slits and windings are permanently spatially and electrically isolated from each other by the low-viscosity adhesive.

After the adhesive bond has cured, the brazed-on carrier plate is separated from the fixed coil sheet metal. The residue from the carrier plate ridges is removed from the surface of the coil by way of a milling operation. The adhesive that seeped through during gluing is also removed by milling.

In the case of flat or minimally curved coils, the carrier plate can first be roughly sawed off in the region of the ridges at a sufficient distance from the coil sheet metal.

The end product is a coil 45 made of copper, which is fixed by at least one adhesive, and has very tight and narrowly separated windings 46.1 to 46.9, which are disposed on an optionally non-conductive plastic carrier material made of plexiglass 47. The coil is produced from copper sheet metal having a thickness of 0.5 mm, or even less, using the method described above. On a surface area of less than 9 cm², 9.5 windings having a thickness of 0.05 to 1 millimeter are accommodated and separated from each other by a 0.03 millimeter separating slit.

No dimensions that are provided shall be interpreted to be limiting, but rather are suggested only by way of example. In fact, these can be adapted to the intended application of the coil. The same also applies to the number of windings of the coil.

The coil sheet metal, and optionally the precursors thereof, are cleaned in an ultrasonic bath using a suitable cleaning solution.

### SECOND EMBODIMENT

### Production of a Three-Dimensional Coil

If curved coils are produced using the method, a carrier plate must be used that comprises spacers that also have a surface shape that complements the sheet metal for the coil. The individual machining steps for producing the carrier plate, including the spacers, are largely identical to embodiment 1.

However, the sheet metal for the coil is produced, first on one side, from a block, by way of milling, and thereby exactly adapted to the height of the spacers. After fastening the sheet metal to all spacers, the sheet metal is further milled on the free surface so as to obtain the desired geometry, and then machined using a fine cutting laser so as to produce the coil geometry, including the windings.

Such three-dimensional coil structures are fixed to a plastic plate, which is again complementary thereto, by means of an adhesive or simply by using an adhesive, and then removed from the spacers, for example by milling, and cleaned.

1. A method for producing a coil from sheet metal comprising the following steps:
producing a carrier plate having spacers for the sheet metal;
fastening the sheet metal to the spacers of the carrier plate; and
fabricating a coil geometry in the sheet metal.

2. A method according to claim 1, comprising fixing the coil.

3. A method according to claim 2, comprising selecting an adhesive for fixation.

4. A method according claim 1, wherein a plastic plate is glued to the coil using an adhesive.

5. A method according to claim, 1 comprising detaching the coil from the spacers.

6. A method according to claim 1, comprising selecting a sheet metal for the coil that has a thickness of approximately 0.1 to 1 millimeter.

7. An assembly, comprising a carrier plate having spacers and sheet metal for a coil fastened to spacers.

8. A coil comprising windings which are stabilized on spacers of a carrier plate.

9. A coil comprising windings which are fixed using an adhesive and are separated from each other spatially and electrically.

10. A coil according to claim 8, which is glued to a non-conductive plastic carrier.

11. A coil according to claim 8, wherein the winding thickness is approximately 0.05 to 1 millimeter.

12. A coil according to claim 8, which is disposed on a surface area of <5 cm².

13. A coil according to claim 8, comprising a two- or three-dimensional structure.

14. Use of an assembly according to claim 7 for producing a coil.

15. Use of a coil according to claim 8, in a magnetic resonance imaging scanner.

16. A coil according to claim 9, which is glued to a non-conductive plastic carrier.

17. A coil according to claim 9, wherein the winding thickness is approximately 0.05 to 1 millimeter.

18. A coil according to claim 9, which is disposed on a surface area of <5 cm².

19. A coil according to claim 9, comprising a two- or three-dimensional structure.

20. Use of a coil according to claim 9 in a magnetic resonance imaging scanner.
